(19) United States
(12) Patent Application Publication
(10) Pub. No.: US 2011/0186997 A1
(43) Pub. Date: Aug. 4, 2011

(54) BOARD ON CHIP PACKAGE SUBSTRATE AND MANUFACTURING METHOD THEREOF

(75) Inventors: Mi-Sun HWANG, Suwon-si (KR); Myung-Sam Kang, Hwasung-si (KR)

(73) Assignee: SAMSUNG ELECTRO-MECHANICS CO., LTD.

(21) Appl. No.: 12/821,621

(22) Filed: Jun. 23, 2010

(30) Foreign Application Priority Data
Jan. 29, 2010 (KR) 10-2010-0008674

(51) Int. Cl. H01L 23/498; H01L 21/60

(52) U.S. Cl. 257/738; 438/125; 257/E23.069; 257/E21.508

(57) ABSTRACT

A single-layer board on chip package substrate and a method of manufacturing the same are disclosed. The single-layer board on chip package substrate in accordance with an embodiment of the present invention includes an insulator, which has a window perforated therethrough, a wiring pattern, a wire bonding pad and a solder ball pad, which are embedded in one surface of the insulator, and a solder resist layer, which is formed on the one surface of the insulator such that the solder resist layer covers the wiring pattern but at least portions of the wire bonding pad and the solder ball pad are exposed.

### CROSS-REFERENCE TO RELATED APPLICATIONS

This application claims the benefit of Korean Patent Application No. 10-2010-0008674, filed with the Korean Intellectual Property Office on Jan. 29, 2010, the disclosure of which is incorporated herein by reference in its entirety.

### BACKGROUND

1. Technical Field

The present invention is related to a board on chip package substrate and a manufacturing method thereof.

2. Description of the Related Art

Compared to the conventional electronic devices, the latest electronic devices have become increasingly thinner. For this, there has been a demand for smaller-size, higher-performance semiconductor chip packages. With the current trend, a multi-chip package, in which a plurality of semiconductor chips are stacked vertically or arranged on a flat surface and embedded in the package, and a board on chip package, in which a semiconductor chip is attached directly to and sealed in the board to reduce the overall size, are used for semiconductor chip packages.

The board on chip (BOC) is receiving attention as a next generation high-speed semiconductor substrate that is suitable for high-speed DRAM, such as DDR2, because a bare die itself is placed directly on a substrate, by which thermal and electrical losses due to the high speed of DRAM can be minimized, unlike the conventional method in which a semiconductor is mounted on a substrate by using a lead frame. The current capacity of DRAM is rapidly increasing to, for example, 128 MB, 256 MB, 512 MB, 1 GB and 2 GB. In response to a trend toward higher-performance DRAMs, electrical losses have to be minimized by reducing the thickness of the substrate, and the product reliability has to be improved. In the conventional board on chip package, a hole for connecting a semiconductor chip is formed in the center of the substrate, and wire bonding is implemented by the hole.

Even in this conventional board on chip package, the increased number of input/output terminals for higher density has become a problem, and there have been demands for saving the cost of manufacturing the printed circuit board.

### SUMMARY

The present invention provides a single-layer board on chip package substrate and a method of manufacturing the same that can increase the number of input/output terminals for higher density by forming a minute pitch between pads.

An aspect of the present invention provides a single-layer board on chip package substrate. The single-layer board on chip package substrate in accordance with an embodiment of the present invention can include an insulator, which has a window perforated therethrough, a wiring pattern, a wire bonding pad and a solder ball pad, which are embedded in one surface of the insulator, and a solder resist layer, which is formed on the one surface of the insulator such that the solder resist layer covers the wiring pattern but at least portions of the wire bonding pad and the solder ball pad are exposed.

The single-layer board on chip package substrate can further include a semiconductor component, which is mounted on the other surface of the insulator, a wire, which electrically connects the semiconductor component to the wire bonding pad through the window, an encapsulation part, which covers the wire and the wire bonding pad, and a solder ball, which is coupled to the solder ball pad.

Another aspect of the present invention provides a method of manufacturing a single-layer board on chip package substrate. The method in accordance with an embodiment of the present invention can include preparing a member in which two carriers are stacked on either surface of an adhesive layer, forming a wiring pattern, a wire bonding pad and a solder ball pad on each surface of one of the two carriers, separating the two carriers from the adhesive layer, interposing a pair of insulators between the two carriers and interposing a separation layer between the pair of insulators and pressing the carriers, the insulators and the separation layer to one another, in which the wiring pattern, the wire bonding pad and the solder ball pad formed on each carrier are embedded in one surface of each insulator, removing the carriers such that one surface of each of the wiring pattern, the wire bonding pad and the solder ball pad is exposed, coating a solder resist membrane on one surface of each of the insulators from which the carriers are removed, forming a solder resist layer by patterning the solder resist membrane such that at least portions of the wire bonding pad and the solder ball pad are exposed, separating the pair of insulators from the separation layer and perforating a window in the separated insulator.

Yet another aspect of the present invention provides a method of manufacturing a single-layer board on chip package substrate. The method in accordance with an embodiment of the present invention can include preparing a member in which a flexible insulation layer and a metal layer are successively stacked on both surfaces of an adhesive layer, forming a patterned etching resist on surfaces of the two metal layers, forming a wiring pattern, a wire bonding pad and a solder ball pad on a surface of the flexible insulation layer by selectively etching the two metal layers, separating the two flexible insulation layers from the adhesive layer, interposing a pair of insulators between the two flexible insulation layers and interposing a separation layer between the pair of insulators and pressing the flexible insulation layers, the insulators and the separation layer to one another, in which the wiring pattern, the wire bonding pad and the solder ball pad formed on each flexible insulation layer are embedded in one surface of each insulator, forming a solder resist layer by patterning the flexible insulation layer such that at least portions of the wire bonding pad and the solder ball pad are exposed, separating the pair of insulators from the separation layer and perforating a window in the separated insulator.

The method can further include mounting a semiconductor component on the other surface of the insulator, electrically connecting the semiconductor component to the wire bonding pad through the window and coupling a solder ball to the solder ball pad.

The method can further include, after the forming of the solder resist layer, forming a surface treatment layer on the exposed portions of the wire bonding pad and the solder ball pad.

Additional aspects and advantages of the present invention will be set forth in part in the description which follows, and in part will be obvious from the description, or may be learned by practice of the invention.

### BRIEF DESCRIPTION OF THE DRAWINGS

FIGS. 1 and 2 are cross-sectional views illustrating an embodiment of a single-layer board on chip package substrate in accordance with an aspect of the present invention.

FIGS. 3 to 11 illustrate an embodiment of a manufacturing method of a single-layer board on chip package substrate in accordance with another aspect of the present invention.

FIGS. 12 to 20 illustrate another embodiment of a manufacturing method of a single-layer board on chip package substrate in accordance with another aspect of the present invention.

### DETAILED DESCRIPTION

As the invention allows for various changes and numerous embodiments, particular embodiments will be illustrated in the drawings and described in detail in the written description. However, this is not intended to limit the present invention to particular modes of practice, and it is to be appreciated that all changes, equivalents, and substitutes that do not depart from the spirit and technical scope of the present invention are encompassed in the present invention. In the description of the present invention, certain detailed descriptions of related art are omitted when it is deemed that they may unnecessarily obscure the essence of the invention.

A board on chip package substrate and a method of manufacturing the board on chip package substrate in accordance with certain embodiments of the present invention will be described below in more detail with reference to the accompanying drawings. Those components that are the same or are in correspondence are rendered the same reference numeral regardless of the figure number, and redundant descriptions are omitted.

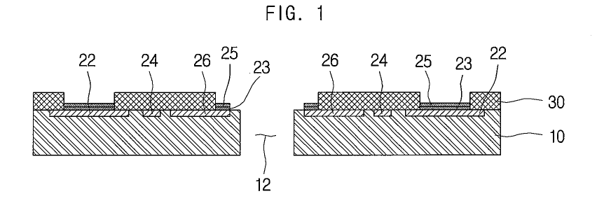

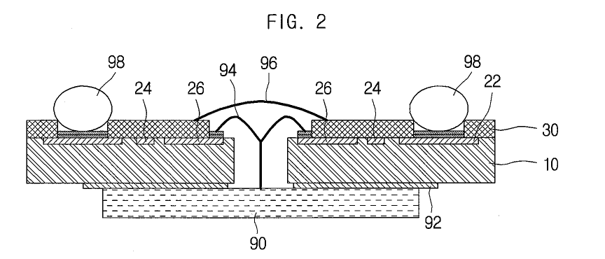

FIG. 1 is a cross-sectional view of a single-layer board on chip package substrate in accordance with an aspect of the present invention. In the single-layer board on chip package substrate in accordance with an embodiment of the present invention, a wiring pattern 24, a wire bonding pad 26 and a solder ball pad 22 are embedded in one surface of an insulator 10, into which a window 12 is perforated. In the present embodiment, since the wiring pattern 24, the wire bonding pad 26, the solder ball pad 22 and the like are all embedded in the insulator 10, not only can pitches between the wiring pattern 24 and the pads 22 and 26 be decreased, but gaps between the wiring pattern 24 and the pads 22 and 26 can be also decreased. This is advantageous for a higher density of the product.

Here, a solder resist layer 30 is formed on the surface, in which the wiring pattern 24, the wire bonding pad 26 and the solder pad 22 are embedded, of the insulator 10. The solder resist layer 30 covers and protects the wiring pattern 24 from the outside and exposes at least portions of the wire bonding pad 26 and the solder ball pad 22.

The wire bonding pad 26 is a part for connection with a semiconductor component 90, which is mounted on the other surface (a lower surface in FIG. 1) of the insulator 10. More specifically, once the semiconductor component 90 is mounted on the other surface of the insulator 10, a wire 94 can be used to electrically connect the semiconductor component 90 to the wire bonding pad 26 through the window 12. Here, the wire 94 and the wire bonding pad 26 can be protected from the outside by being covered by an encapsulation part 96.

The solder ball pad 22 is where a solder ball 98 is coupled. The solder ball 98 coupled to the solder ball pad 22 can be connected to an external device such as a main board (not shown), and thus the single-layer board on chip package substrate of the present embodiment can input/output signals.

Hitherto, the structure of a single-layer board on chip package substrate in accordance with an embodiment of the present invention has been described. Hereinafter, a method of manufacturing the single-layer board on chip package substrate will be described. Throughout the description of the present embodiment, detailed descriptions of the structure of the single-layer board on chip package substrate will be omitted hereinafter because its structural features have been described above.

### Embodiment 1

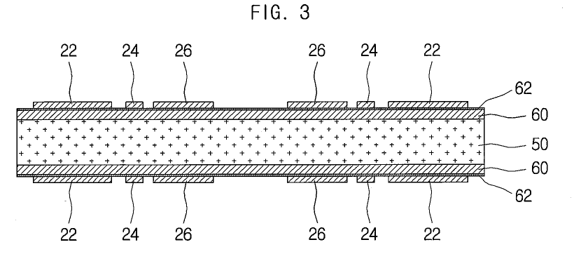

FIGS. 3 to 11 illustrate each process of manufacturing a single-layer board on chip package substrate in accordance with an embodiment of the present invention.

First, a member in which two carriers 60 are stacked on either surface of an adhesive layer 50 is prepared, and then a wiring pattern 24, a wire bonding pad 26 and a solder ball pad 22 are formed on one surface of each of the two carriers 60 (refer to FIG. 3). The carriers 60 can be made of a metallic material, such as copper. In order to form the wiring pattern 24, the wire bonding pad 26 and the solder ball pad 22, a seed layer 62 is formed on the surface of the metallic carrier 60 by way of electroless plating, and then an electro plating method can be used.

Meanwhile, as illustrated in FIG. 3, by using the member having the two carriers 60 stacked on either surface thereof, two products can be manufactured at one time in a single process, thus improving the production yield.

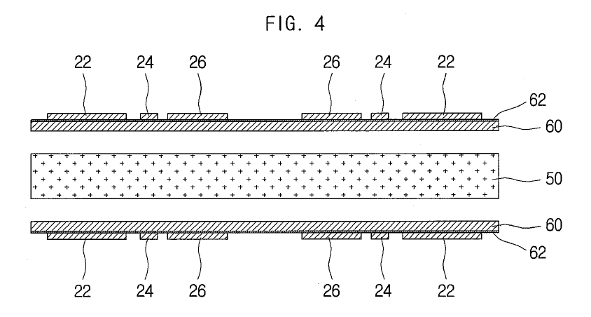

Next, the two carriers 60 are separated from the adhesive layer 50 (refer to FIG. 4). Here, if the adhesive layer 50 is made of a thermoplastic material, the adhesion of the adhesive layer 50 can be weakened by heating the adhesive layer 50 prior to the separation of the carriers 60 from the adhesive layer 50. Thus, the two carriers 60 can be readily separated from the adhesive layer 50.

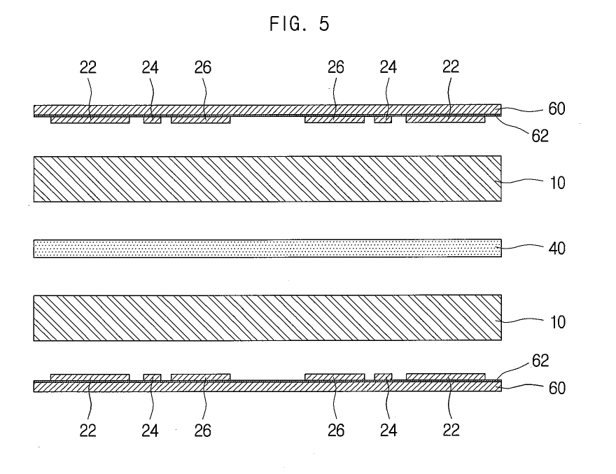

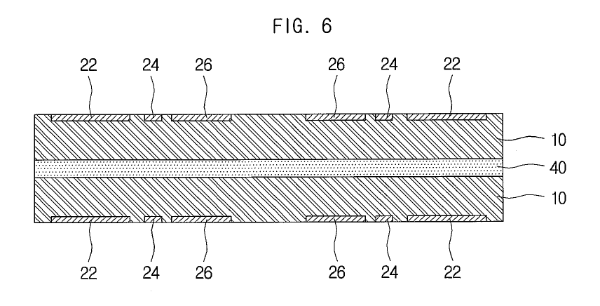

Next, as illustrated in FIG. 5, a pair of insulators 10 are interposed between the carriers 60, and a separation layer 40 is interposed between the pair of insulators 10. Then, the carriers 60, the insulators 10 and the separation layer 40 are pressed to one another. Specifically, after disposing the carriers 60 in such a way that the wiring pattern 24 and the pads 22 and 26 formed on one surface of one of the two carriers 60 face the wiring pattern 24 and the pads 22 and 26 formed on one surface of the other of the two carriers 60, the insulators 10 can be interposed between the carriers 60, and then the separation layer 40 can be interposed between the insulators 10. By disposing and pressing them to one another, the wiring pattern 24, the wire bonding pad 26 and the solder ball pad 22 formed on each carrier 60 can be embedded in one surface of each insulator 10 (refer to FIG. 6). Meanwhile, a material having an excellent separation characteristic, for example, Teflon, can be used for the separation layer 40.

By performing a pressing process to both surfaces of the separation layer 40, two products can be manufactured at one time in a single process, and thus it is expected that the production yield can be improved.

Then, the carriers 60 are removed so that surfaces of the wiring pattern 24, the wire bonding pad 26 and the solder ball pad 22 can be exposed, as illustrated in FIG. 6.

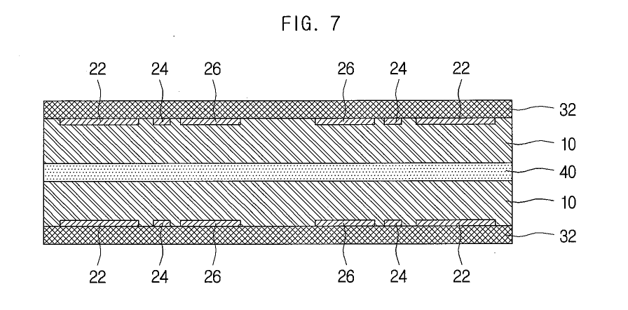

Next, as illustrated in FIG. 7, a solder resist membrane 32 is coated on the entire surface of each of the insulators 10, from which the carriers 60 are removed. Here, the solder resist membrane 32 can be coated by coating a liquid-state material over the entire surface of the insulator 10 or by adhering a film-type material.

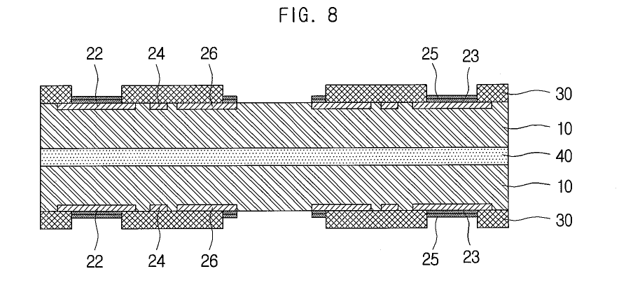

Next, a solder resist layer 30 is formed by patterning the solder resist membrane 32 such that at least portions of the wire bonding pad 26 and the solder ball pad 22 are exposed (refer to FIG. 8). For this, a photolithography process including partial exposing and developing processes can be used.

After forming the solder resist layer 30, a process for forming surface treatment layers, for example, a nickel plating layer 23 and a gold plating layer 25, can also be performed on the exposed portions of the wire bonding pad 26 and the solder ball pad 22. The surface treatment layers 23 and 25 can function to prevent oxidation of the wire bonding pad 26 and the solder ball pad 22.

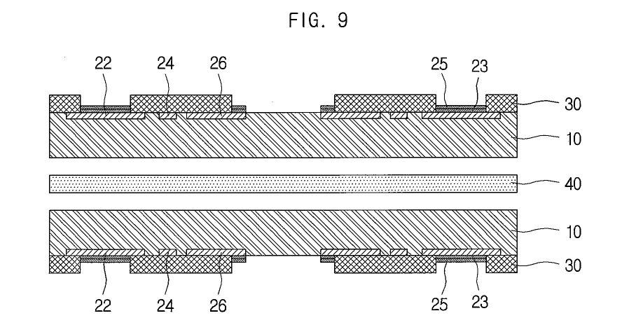

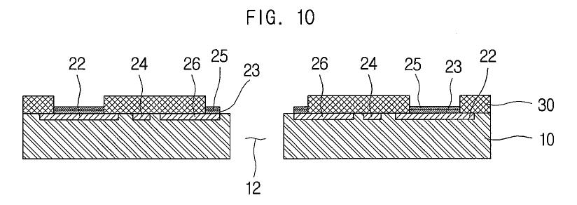

Then, the insulators 10 are separated from the separation layer 40 (refer to FIG. 9), and the window 12 is perforated in the separated insulator 10 (refer to FIG. 10). A device such as a router bit can be used for perforating the window 12, and it is also possible that other devices than the router bit can be used.

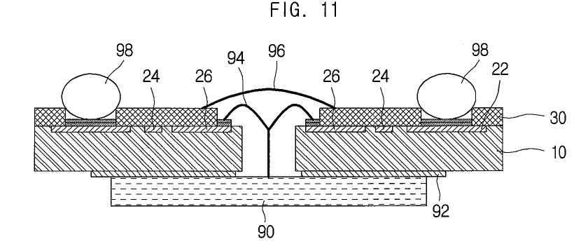

Next, as illustrated in FIG. 11, a solder ball 98 is coupled to the solder ball pad 22, and a semiconductor component 90 is adhered to the other surface of the insulator 10 by using an adhesive 92. Then, a wire 94 made of a metallic material, such as gold, is used for wire bonding the semiconductor component 90 to the wire bonding pad 26 through the window 12 so that a board on chip package can be implemented.

Here, a process for forming an encapsulation part 96 is performed in order to protect the wire 94 and the wire bonding pad 26 from the outside.

### Embodiment 2

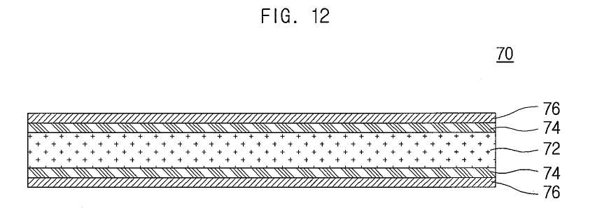

FIGS. 12 to 20 illustrate each process of manufacturing a single-layer board on chip package substrate in accordance with another embodiment of the present invention.

First, as illustrated in FIG. 12, a flexible insulation layer 74, such as polyimide (PI), and a metal layer 76 are successively stacked on both surfaces of an adhesive layer 72. Specifically, a member in which single-side flexible copper clad laminates (FCCL) 74 and 76 are stacked on both surfaces of the adhesive layer 72 can be prepared.

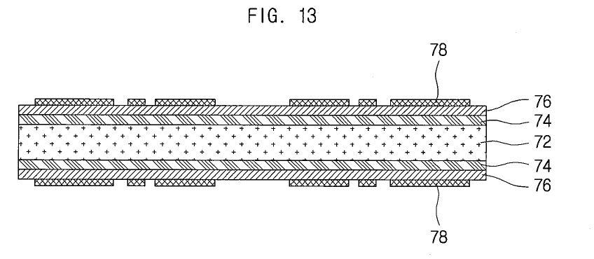

Then, as illustrated in FIG. 13, a patterned etching resist 78 is formed on the surfaces of the two metal layers 76. The etching resist 78 is patterned to correspond to positions of a wiring pattern 24, a wire bonding pad 26 and a solder ball pad 22 to be formed.

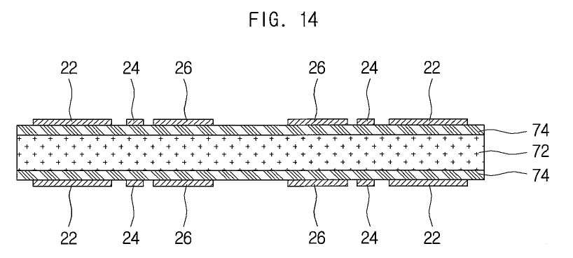

Next, the two metal layers 76 are selectively etched by using an etching solution. As a result, the wiring pattern 24, the wire bonding pad 26 and the solder ball pad 22 are formed on the surface of the flexible insulation layer 74, as illustrated in FIG. 14.

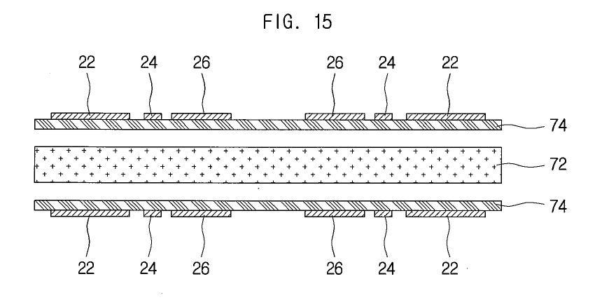

Next, as illustrated in FIG. 15, the two flexible insulation layers 74 are separated from the adhesive layer 72.

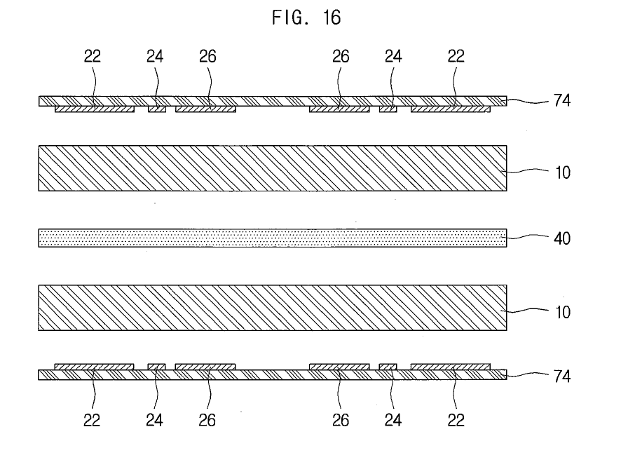

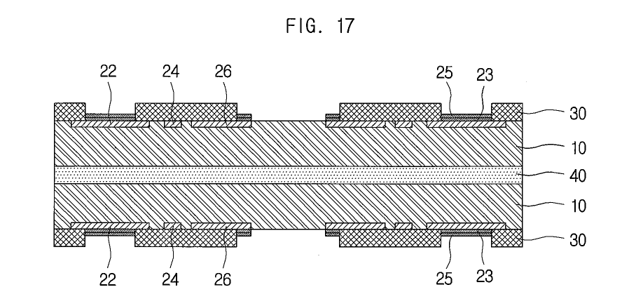

Then, as illustrated in FIG. 16, a pair of insulators 10 are interposed between the flexible insulation layers 74, and a separation layer 40 is interposed between the pair of insulators 10. Then, the flexible insulation layers 74, the insulators 10 and the separation layer 40 are pressed to one another. Specifically, after disposing the flexible insulation layers 74 in such a way that the wiring pattern 24 and the pads 22 and 26 formed on one surface of one of the two flexible insulation layers 74 face the wiring pattern 24 and the pads 22 and 26 formed on one surface of the other of the two flexible insulation layers 74, the insulators 10 can be interposed between the flexible insulation layers 74, and then the separation layer 40 can be interposed between the insulators 10. By disposing and pressing them to one another, the wiring pattern 24, the wire bonding pad 26 and the solder ball pad 22 formed on each flexible insulation layer 74 can be embedded in one surface of each insulator 10 (refer to FIG. 17). Meanwhile, a material having an excellent separation characteristic, for example, Teflon, can be used for the separation layer 40.

By performing a pressing process to both surfaces of the separation layer 40, two products can be manufactured at one time in a single process, and thus it is expected that the production yield can be improved.

Next, a solder resist layer 30 is formed by patterning the flexible insulation layer 74 such that at least portions of the wire bonding pad 26 and the solder ball pad 22 are exposed (refer to FIG. 17). That is, the flexible insulation layer 74, which functions as a supporting body for the wiring pattern 24 and the pads 22 and 26, can be used for the solder resist layer 30.

After forming the solder resist layer 30, a process for forming surface treatment layers, for example, a nickel plating layer 23 and a gold plating layer 25, can also be performed on the exposed portions of the wire bonding pad 26 and the solder ball pad 22. The surface treatment layers 23 and 25 can function to prevent oxidation of the wire bonding pad 26 and the solder ball pad 22.

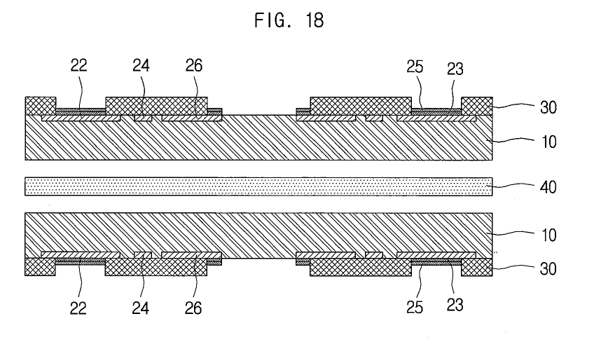

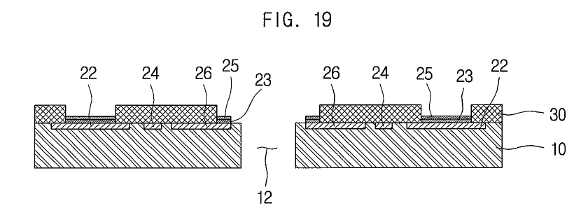

Then, the insulators 10 are separated from the separation layer 40 (refer to FIG. 18), and the window 12 is perforated in the separated insulator 10 (refer to FIG. 19). A device such as a router bit can be used for perforating the window 12, and it is also possible that other devices than the router bit can be used.

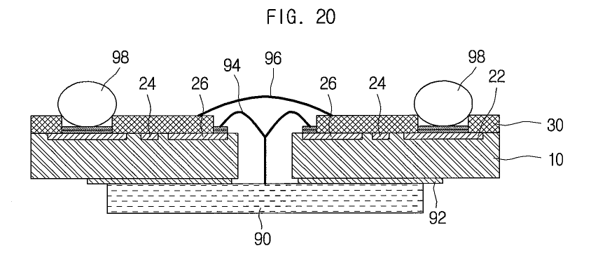

Next, as illustrated in FIG. 20, a solder ball 98 is coupled to the solder ball pad 22, and a semiconductor component 90 is adhered to the other surface of the insulator 10 by using an adhesive 92. Then, a wire 94 made of a metallic material, such as gold, is used for wire bonding the semiconductor component 90 to the wire bonding pad 26 through the window 12 so that a board on chip package can be implemented.

Here, a process for forming an encapsulation part 96 is performed in order to protect the wire 94 and the wire bonding pad 26 from the outside.

By utilizing certain embodiments of the present invention as set forth above, a single-layer board on chip package substrate that can increase the number of input/output terminals for higher density by forming a minute pitch between pads is provided.

While the spirit of the invention has been described in detail with reference to certain embodiments, the embodiments are for illustrative purposes only and shall not limit the invention. It is to be appreciated that those skilled in the art can change or modify the embodiments without departing from the scope and spirit of the invention.

As such, many embodiments other than those set forth above can be found in the appended claims.

What is claimed is:

1. A single-layer board on chip package substrate comprising:
an insulator having a window perforated therethrough;
a wiring pattern, a wire bonding pad and a solder ball pad embedded in one surface of the insulator; and
a solder resist layer formed on the one surface of the insulator such that the solder resist layer covers the wiring pattern but at least portions of the wire bonding pad and the solder ball pad are exposed.

2. The single-layer board on chip package substrate of claim 1, further comprising:
a semiconductor component mounted on the other surface of the insulator;
a wire electrically connecting the semiconductor component to the wire bonding pad through the window;
an encapsulation part covering the wire and the wire bonding pad; and
a solder ball coupled to the solder ball pad.

3. A method of manufacturing a single-layer board on chip package substrate, the method comprising:
preparing a member in which two carriers are stacked on either surface of an adhesive layer;
forming a wiring pattern, a wire bonding pad and a solder ball pad on each surface of one of the two carriers;
separating the two carriers from the adhesive layer;
interposing a pair of insulators between the two carriers and interposing a separation layer between the pair of insulators and pressing the carriers, the insulators and the separation layer to one another, wherein the wiring pattern, the wire bonding pad and the solder ball pad formed on each carrier are embedded in one surface of each insulator;
removing the carriers such that one surface of each of the wiring pattern, the wire bonding pad and the solder ball pad is exposed;
coating a solder resist membrane on one surface of each of the insulators from which the carriers are removed;
forming a solder resist layer by patterning the solder resist membrane such that at least portions of the wire bonding pad and the solder ball pad are exposed;
separating the pair of insulators from the separation layer; and
perforating a window in the separated insulator.

4. The method of claim 3, further comprising:
mounting a semiconductor component on the other surface of the insulator;
electrically connecting the semiconductor component to the wire bonding pad through the window; and
coupling a solder ball to the solder ball pad.

5. The method of claim 3, further comprising, after the forming of the solder resist layer, forming a surface treatment layer on the exposed portions of the wire bonding pad and the solder ball pad.

6. A method of manufacturing a single-layer board on chip package substrate, the method comprising:
preparing a member in which a flexible insulation layer and a metal layer are successively stacked on both surfaces of an adhesive layer;
forming a patterned etching resist on surfaces of the two metal layers;
forming a wiring pattern, a wire bonding pad and a solder ball pad on a surface of the flexible insulation layer by selectively etching the two metal layers;
separating the two flexible insulation layers from the adhesive layer;
interposing a pair of insulators between the two flexible insulation layers and interposing a separation layer between the pair of insulators and pressing the flexible insulation layers, the insulators and the separation layer to one another, wherein the wiring pattern, the wire bonding pad and the solder ball pad formed on each flexible insulation layer are embedded in one surface of each insulator;
forming a solder resist layer by patterning the flexible insulation layer such that at least portions of the wire bonding pad and the solder ball pad are exposed;
separating the pair of insulators from the separation layer; and
perforating a window in the separated insulator.

7. The method of claim 6, further comprising:
mounting a semiconductor component on the other surface of the insulator;
electrically connecting the semiconductor component to the wire bonding pad through the window; and
coupling a solder ball to the solder ball pad.

8. The method of claim 6, further comprising, after the forming of the solder resist layer, forming a surface treatment layer on the exposed portions of the wire bonding pad and the solder ball pad.
